(19) United States
(12) Patent Application Publication
(10) Pub. No.: US 2012/0042949 A1
(43) Pub. Date: Feb. 23, 2012

(54) SOLAR CONCENTRATOR

(75) Inventor: Eli Shifman, Hod Hasharon (IL)

(73) Assignee: AEROSUN TECHNOLOGIES AG., Zug (CH)

(21) Appl. No.: 13/258,455

(22) PCT Filed: May 6, 2010
(86) PCT No.: PCT/IB2010/051994

§ 371 Date: Sep. 22, 2011

Related U.S. Application Data
(60) Provisional application No. 61/178,069, filed on May 14, 2009.

(51) Int. Cl. H01L 31/0232; B23P 25/00; G02B 5/10; H01L 31/18

(52) U.S. Cl. 136/259; 29/890.033; 29/458; 359/853

(57) ABSTRACT

Apparatus (24), including a photovoltaic cell (22) and a concave primary reflector (26) configured to focus a first portion of incoming radiation toward a focal point (30). The apparatus also includes a secondary reflector (38), which is positioned between the concave primary reflector and the focal point so as to direct the focused radiation toward the photovoltaic cell, and which has a central opening (44) aligned with the photovoltaic cell. The apparatus further includes a transmissive concentrator (54), positioned so as to focus a second portion of the incoming radiation through the central opening onto the photovoltaic cell.

### CROSS-REFERENCE TO RELATED APPLICATIONS

This application claims the benefit of U.S. Provisional Patent Application 61/178,069, filed 14 May, 2009, which is incorporated herein by reference.

### FIELD OF THE INVENTION

The present invention relates generally to solar radiation, and specifically to concentrating the radiation.

### BACKGROUND OF THE INVENTION

As electrical energy demand grows, there is an increased interest in efficiently converting solar radiation to electrical energy. Typically, photovoltaic cells implement the conversion, and systems which perform the conversion using non-concentrated as well as concentrated solar radiation are known in the art. Concentrating systems typically use one or more mirrors to effect the concentration.

The description above is presented as a general overview of related art in this field and should not be construed as an admission that any of the information it contains constitutes prior art against the present patent application.

### SUMMARY OF THE INVENTION

An embodiment of the present invention provides apparatus, including:

a photovoltaic cell;

a concave primary reflector configured to focus a first portion of incoming radiation toward a focal point;

a secondary reflector, which is positioned between the concave primary reflector and the focal point so as to direct the focused radiation toward the photovoltaic cell, and which has a central opening aligned with the photovoltaic cell; and

a transmissive concentrator, positioned so as to focus a second portion of the incoming radiation through the central opening onto the photovoltaic cell.

Typically, at least one of the primary reflector and the secondary reflector include a plurality of curved segments.

In a disclosed embodiment the apparatus further includes a tracking device connected to the photovoltaic cell, the primary reflector, the secondary reflector, and the transmissive concentrator, wherein the primary reflector has an aperture, and wherein dimensions of the transmissive concentrator and the aperture differ by no more than a value determined in response to a tracking error of the tracking device.

The transmissive concentrator may have a concentrator-dimension larger than a largest dimension of the secondary reflector. Alternatively, the transmissive concentrator and the secondary reflector may have congruent external dimensions.

A shape of the transmissive concentrator may be geometrically similar to the central opening.

The apparatus may include a homogenizer, positioned between the secondary reflector and the photovoltaic cell, which may redirect at least some of the focused radiation onto the photovoltaic cell. The homogenizer may redirect at least some of the second portion of the radiation onto the photovoltaic cell.

Typically, the central opening is aligned and dimensioned within the secondary reflector so as to receive none of the focused radiation.

In an alternative embodiment the transmissive concentrator has a concentrator-dimension larger than a largest dimension of the central opening.

In one embodiment the concave primary reflector includes a paraboloidal reflector.

There is further provided a method, including:

stamping flat metal plates so as to create a plurality of segments having a predetermined curved shape; and

joining the curved segments together in order to create a curved reflector.

The method may include applying a reflective coating to the metal plates prior to stamping the plates. Typically, a deformation caused by stamping the flat metal plates is within a tolerance limit of the reflective coating.

The predetermined curved shape and the curved reflector may be sections of a common paraboloid.

There is further provided a method, including:

configuring a concave primary reflector to focus a first portion of incoming radiation toward a focal point;

positioning a secondary reflector between the concave primary reflector and the focal point so as to direct the focused radiation toward a photovoltaic cell;

aligning a central opening in the secondary reflector with the photovoltaic cell; and

positioning a transmissive concentrator to focus a second portion of the incoming radiation through the central opening onto the photovoltaic cell.

There is further provided apparatus, including:

a plurality of flat metal plates which are configured to form respective curved segments having respective predetermined curved shapes; and

at least one joint which holds the curved segments together in order to create a curved reflector.

The present invention will be more fully understood from the following detailed description of the embodiments thereof, taken together with the drawings, in which:

### BRIEF DESCRIPTION OF THE DRAWINGS

FIGS. 1A, 1B, and 1C, schematically illustrate components of a solar collector, according to an embodiment of the present invention;

FIG. 2A is a schematic diagram showing irradiance at the position of a secondary reflector of the solar collector, due to reflection from a primary reflector, and FIG. 2B is a graph of the irradiance vs. distance, according to embodiments of the present invention;

FIGS. 3A and 3B illustrate components of a concentrating photovoltaic (CPV) system, according to an alternative embodiment of the present invention;

FIG. 4A illustrates a design for a cell mount, and FIG. 4B illustrates an alternative design for the cell mount, according to embodiments of the present invention;

FIG. 5A is a schematic diagram showing irradiance at the position of a secondary reflector of the CPV system of FIGS. 3A and 3B, due to reflection from a primary reflector, and

FIG. 5B is a graph of the irradiance vs. distance, according to embodiments of the present invention;

FIG. 6 is a schematic sectional side view of a matrix of CPV systems, according to an embodiment of the present invention;

FIGS. 7A, 7B, and 7C are schematic front, back and side views respectively of a primary reflector, according to an embodiment of the present invention;

FIG. 8 is a schematic front view of a primary reflector, according to an alternative embodiment of the present invention;

FIG. 9A is a schematic front view of segments of a primary reflector, and FIG. 9B is a schematic plan view of a plane sheet for producing some of the segments, according to an embodiment of the present invention;

FIG. 10A and FIG. 10B illustrate the reduction in deformation achieved by constructing a paraboloidal reflector from smaller segments, according to embodiments of the present invention; and

FIG. 11 is a schematic, pictorial illustration showing assembly of the matrix of FIG. 6, according to an embodiment of the present invention.

### DETAILED DESCRIPTION OF EMBODIMENTS

### Overview

Some embodiments of the present invention provide improved methods for concentrating solar radiation in a concentrating photovoltaic (CPV) system. An arrangement of reflectors comprises a primary concave reflector which reflects incoming solar radiation towards a focus. The rays from the primary reflector are intercepted by a secondary reflector which directs the rays to a solar cell.

Incoming solar rays which would normally be shaded from the primary reflector by the secondary reflector are intercepted by a transmissive ray concentrator, typically a Fresnel or refractive lens. The concentrator converges the intercepted rays towards the secondary reflector. The inventors have determined that there is a central region of the secondary reflector which receives no rays from the primary reflector. An opening is provided in this central region, permitting the converged rays from the concentrator to pass through the secondary reflector to the solar cell. Because of its positioning in the central region of the secondary reflector, the opening does not prevent passage of rays from the primary reflector to the solar cell. Thus, all incoming solar rays may be concentrated onto the same solar cell.

One or both of the reflectors in the CPV system may be produced by joining a plurality of metal plates so as to create the required curved reflector shape. Each metal plate is typically formed by stamping respective plane metal sheets, so forming respective segments of the reflector being produced. By forming a reflector from a plurality of segments stamped from plane sheets, the overall deformation from a plane to the required curved shape is substantially reduced compared to the deformation engendered by stamping a single metal sheet. The plane metal sheets may be pre-covered with reflective material and then stamped into their required shape. By forming the reflector from segments, the deformation is sufficiently reduced to prevent degradation of the reflective properties of the sheeting by the stamping.

### DETAILED DESCRIPTION

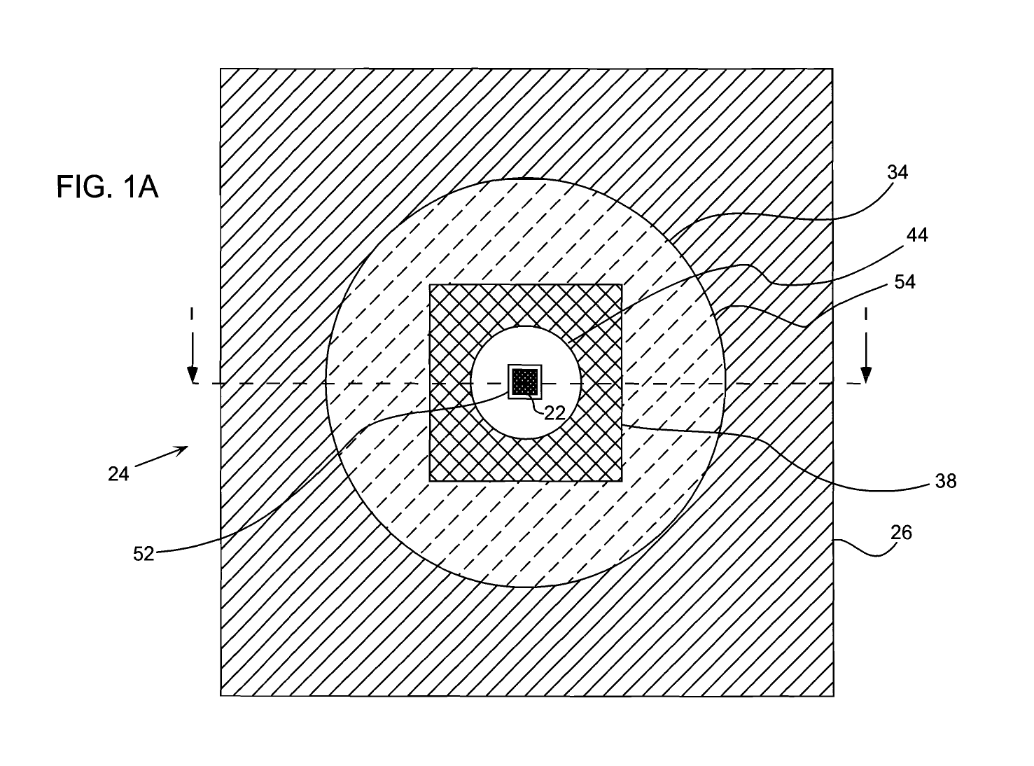

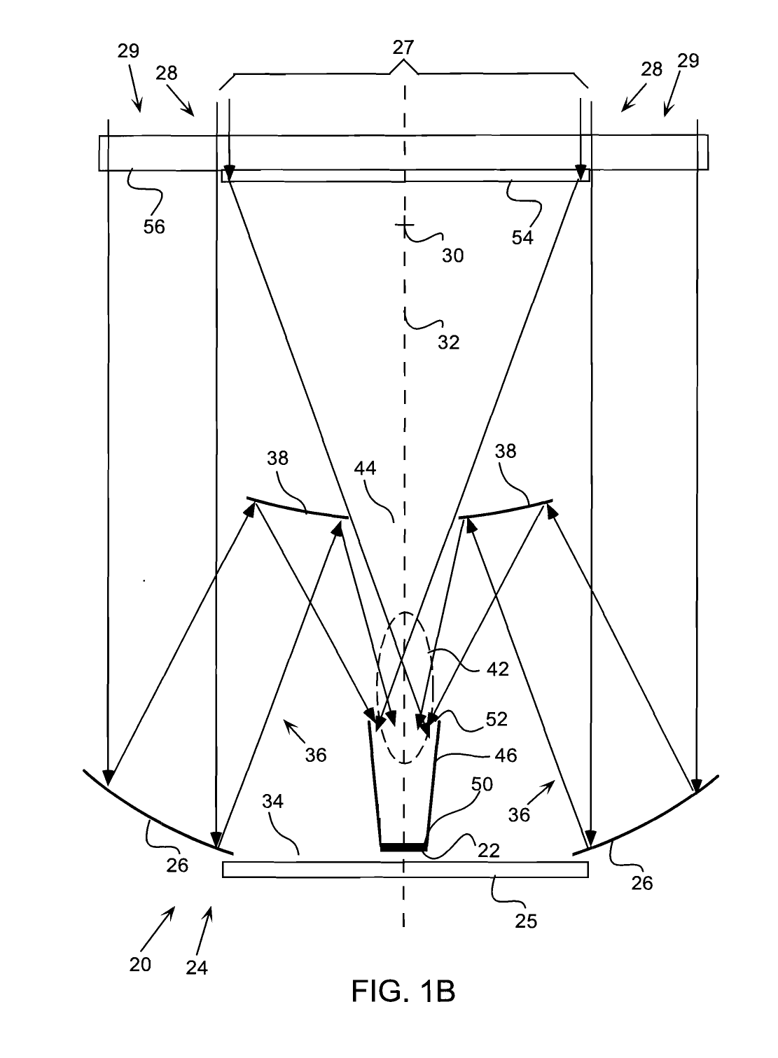

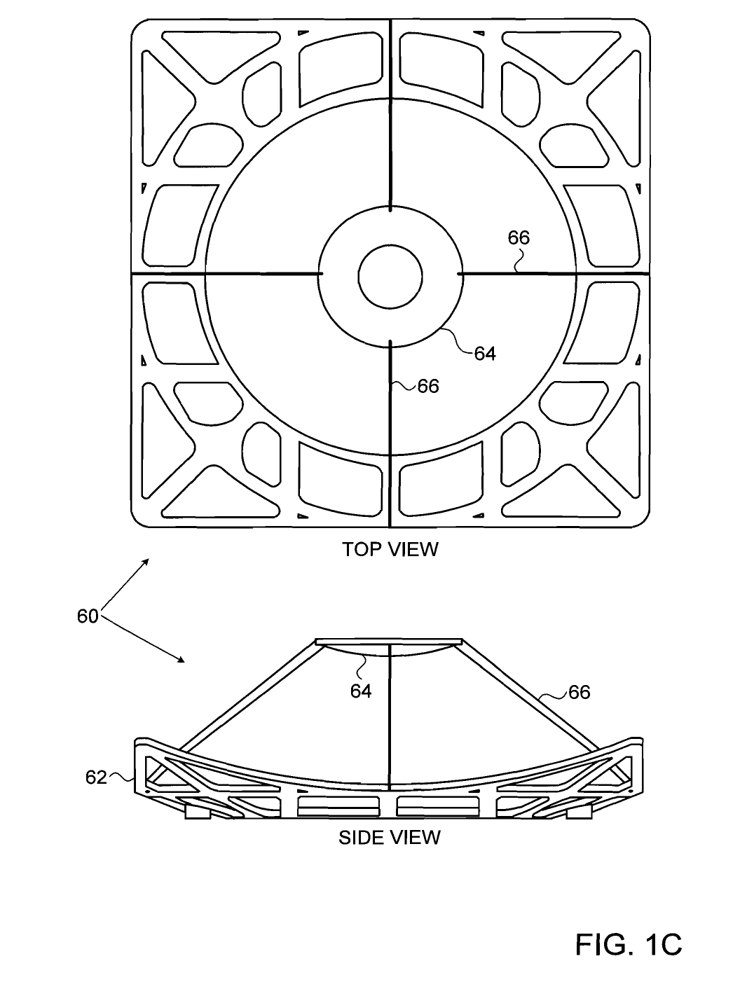

Reference is now made to FIGS. 1A, 1B, and 1C, which schematically illustrate components of a solar collector 20, according to an embodiment of the present invention. Collector 20 acts as a concentrating collector, concentrating incoming solar radiation energy in the form of parallel solar rays 28 onto a cell 22, the cell converting the radiation to another form of energy. Typically, and as assumed in the following description, cell 22 comprises a photovoltaic cell, which absorbs the concentrated radiation energy and generates electric power from a portion of the absorbed energy. Thus collector 20 together with cell 22 act as a concentrating photovoltaic (CPV) system 24. In some embodiments cell 22 has a generally square outline, although there is no limitation on the shape of the cell. Suitable CPV cells for use in system 24 comprise, but are not limited to, a CTJ Photovoltaic Cell produced by Emcore Corporation of Albuquerque, N. Mex., or a CDO-100-C3MJ Concentrator Solar Cell produced by Spectrolab, Inc. of Sylmar Calif.

Typically, CPV system 24 is mounted on a tracking device 25, which rotates the system so that axis 32 points towards the sun. For simplicity, some supports connecting elements of system 24 together and to the tracking device are not shown in FIGS. 1A, 1B and 1C.

FIG. 1A is a schematic top view of components of CPV system 24, and FIG. 1B is a sectional side view of the system taken on a line I-I of FIG. 1A. For clarity, elements supporting the components of the system are not shown in the FIGS. 1A and 1B. FIG. 1C schematically illustrates supports for some of the components of the system. System 24 comprises a primary concentrating concave reflector 26, which is assumed to have an approximately square outline. Reflector 26 may have any concave shape, or combination of shapes, which concentrate incoming approximately parallel light to a focal region. Such shapes include, but are not limited to, spherical and aspherical shapes. By way of example, reflector 26 is assumed to be formed as a paraboloid having an axis of symmetry 32 and a focal point 30 on the axis.

Reflector 26 is typically formed with an aperture 34 symmetrically located at its center.

Incoming solar rays 28 are comprised of two groups of rays: a central group 27 of rays, and a peripheral group 29 of the rays. As explained in more detail below, central group 27 are diverted by a transmissive concentrator 54. Peripheral group 29 transmit directly to the primary reflector and are redirected as reflected rays 36 towards focal point 30.

Reflected rays 36 are intercepted by a secondary reflector 38 before they reach point 30. The secondary reflector has an axis of symmetry that is substantially coincident with axis 32. The secondary reflector is positioned to reflect rays 36 towards the primary reflector, so that the rays reflected from the secondary reflector converge to a focal region 42. Region 42 is approximately centered on axis 32, and is located between the primary and secondary reflectors.

Secondary reflector 38 may be plane or curved, and if curved, it may be concave or convex. Hereinbelow, by way of example, the secondary reflector is assumed to be spherically convex.

The secondary reflector has an opening 44, symmetrically disposed with respect to axis 32. As explained in more detail below, opening 44 allows central group 27 of incoming rays 28 to reach the cell. Typically opening 44 has the same shape as the transmissive concentrator, and in this embodiment is circular, although in some embodiments the opening may be non-circular.

Ray concentrator 54 is positioned above the secondary reflector to intercept central group 27 of incoming rays 28. Concentrator 54 typically comprises a Fresnel lens or a converging lens made from glass or transparent plastic. The concentrator is configured to divert the central group of rays through opening 44, to region 42.

In some embodiments system 24 comprises a transparent window 56 above concentrator 54. Window 56 serves to shield the other elements of system 24 from dust or other material that could reduce the efficiency of operation of the system. Concentrator 54 may be connected to the window using optical cement, so that the window acts as a support for the concentrator.

Because central group 27 of rays are diverted (by concentrator 54) towards region 42, the central ray group does not directly transmit to reflector 26. To accommodate tracking errors, aperture 34 is typically configured to have dimensions somewhat smaller than concentrator 54. The reduction in dimensions is typically based on an expected error of the tracking system, and enables collection of rays that miss the concentrator because of the tracking error.

In order to collect the rays passing through region 42 onto cell 22, solar concentrator 20 comprises a homogenizer 46, which is typically formed as a solid element from an optically clear glass designed to direct the incoming radiation, by total internal reflection, onto the cell.

Alternatively, homogenizer 46 may comprise an open tubular element having an axis of symmetry that is generally coincident with axis 32. In this case, the homogenizer has a reflective inner surface and it is typically configured to have a lower opening 50 that surrounds and mates with cell 22. The homogenizer has an upper opening 52 that is larger than its lower opening. In some alternative embodiments homogenizer 46 is in the form of a hollow truncated cone or pyramid, and in one embodiment the homogenizer comprises a hollow truncated square pyramid, having upper and lower openings that are square.

It will be understood that without ray concentrator 54, some of rays 27 would be shaded from the primary reflector by the secondary reflector. Concentrator 54 ensures that all of rays 27 are directed to homogenizer 46.

In some embodiments cell 22 requires cooling in order to perform its energy conversion function efficiently. For example, semiconducting photovoltaic cells for use in CPV systems typically only convert about 40% of their incident radiant energy to electric energy, so that the remainder is converted to heat. The cooling provided to cell 22 may be passive cooling, typically relying on natural convection of air surrounding the cell and/or of air surrounding heat conducting fins that conduct the heat from the cell. Alternatively or additionally, the cooling provided to the cell may comprise active cooling, which typically uses forced flow of a fluid such as air or water over a rear surface of the cell. For clarity and simplicity, mechanisms for providing the cooling are not shown in FIGS. 1A, 1B and 1C, but mechanisms for providing such cooling are described below. It will be appreciated that locating cell 22 in or close to aperture 34, so that a rear surface of the cell is easily accessible from the rear of the primary reflector, facilitates provision of active or passive cooling to the cell.

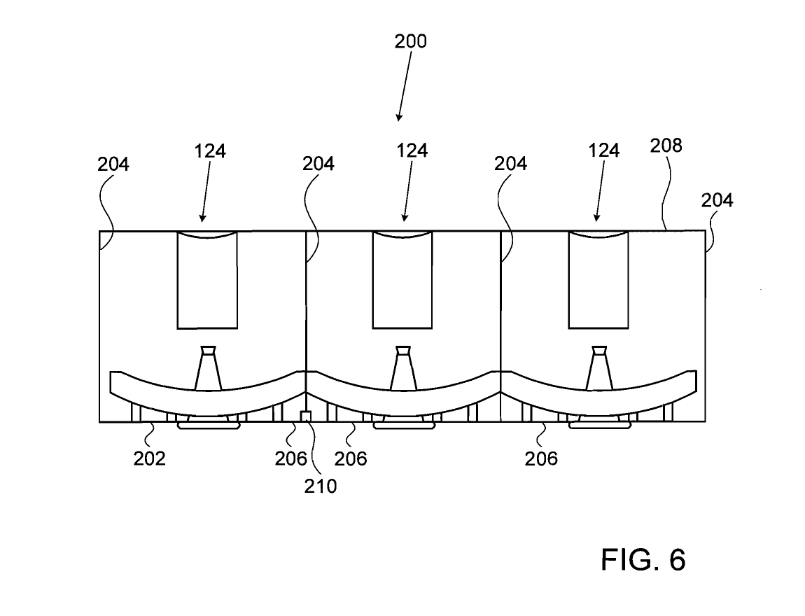

FIG. 1C illustrates a side view and a top view of a mounting 60 for primary reflector 26 and secondary reflector 38. Elements of mounting 60 are typically formed from plastic, using an injection molding process. The mounting comprises a lower skeleton-like section 62, which has an interior shape that is paraboloidal. Section 62 retains primary reflector 26 and has dimensions corresponding to those of the reflector. Mounting 60 also comprises an upper section 64 having a convex shape. Section 64 retains secondary reflector 38 and has dimensions corresponding to those of the secondary reflector, including a hole corresponding to opening 44 of the reflector. Sections 62 and 64 are connected together by thin supports 66 in order to minimize shading losses. The supports serve to hold the two reflectors fixed in their correct positions and orientations with respect to each other. Typically, mounting 60 may be used in a production phase to pre-assemble and align the primary and secondary reflectors as a composite unit, for maximum accuracy, so that the unit (the mounting with its reflectors) is available for a final assembly phase. The final assembly phase typically includes incorporating the composite unit in a system mounting panel, such as is exemplified in the description of matrix 200 (FIG. 6) below.

Table I below gives characteristics of components of a first exemplary embodiment of system 24. The dimensions given in Table I are approximate.

TABLE I

| Component | Characteristics |
|---|---|
| Concentrator 54 | Circular Fresnel lens, diameter 180 mm, focal |
| | length 190 mm |
| Secondary reflector 38 | Convex spherical mirror, square 92 mm × 92 mm, |
| | radius 200 mm. Central opening 44 in the mirror |
| | is circular, corresponding to the shape of |
| | concentrator 54. Opening 44 has a diameter of 50 |
| | mm. |
| Primary reflector 26 | Paraboloidal, square 250 mm × 250 mm, focal |
| | length 127 mm. Central aperture 34 is circular |
| | with diameter 180 mm (corresponding with the |
| | shape and diameter of the Fresnel lens). |
| Solar cell 22 | Square, 10 mm × 10 mm |
| Homogenizer 46 | Square truncated pyramid, of BK7 optical glass. |
| | Length 34 mm, upper dimensions 22 mm × 22 |
| | mm, lower dimensions 9.8 mm × 9.8 mm |
| | (corresponding to, but slightly smaller than, the |
| | solar cell dimensions). |

Table II below gives typical approximate distances between components of the first exemplary embodiment of system 24.

TABLE II

| Components | Distance between Components |
|---|---|
| Concentrator 54-secondary reflector 38 | 153 mm |
| Secondary reflector 38-top of | 44 mm |
| homogenizer 46 | |
| Solar cell 22-aperture 34 | 17 mm |

Table III below gives characteristics of components of a second exemplary embodiment of system 24. The dimensions given in Table III are approximate.

TABLE III

| Component | Characteristics |
|---|---|
| Concentrator 54 | Circular Fresnel lens, diameter 130 mm, focal |
| | length 220 mm |
| Secondary reflector 38 | Convex hyperboloidal mirror, square 90 mm × 90 |
| | mm, hyperbola defined as radius 200 mm at the |
| | vertex and conic constant, K, equal to −4. Central |
| | opening 44 in the mirror is circular, |
| | corresponding to the shape of concentrator 54. |
| | Opening 44 has a diameter of 38 mm. |
| Primary reflector 26 | Paraboloidal, square 230 mm × 230 mm, focal |
| | length 127 mm. Central aperture 34 is circular |
| | with diameter 120 mm (corresponding with the |
| | shape of the Fresnel lens). The diameter is |
| | slightly less than the lens to allow for tracking |
| | errors. |
| Solar cell 22 | Square, 5.5 mm × 5.5 mm |
| Homogenizer 46 | Square truncated compound parabolic |
| | concentrator, of BK7 optical glass. Length 23 |
| | mm, upper dimensions 14.36 mm × 14.36 mm, |
| | lower dimensions 5.4 mm × 5.4 mm |
| | (corresponding to, but slightly smaller than, the |
| | solar cell dimensions). |

Table IV below gives typical approximate distances between the components of system 24 listed in Table III.

TABLE IV

| Components | Distance between Components |
|---|---|
| Concentrator 54-secondary reflector 38 | 163.2 mm |
| Secondary reflector 38-top of | 67.8 mm |
| homogenizer 46 | |
| Secondary reflector 38-solar cell 22 | 90.8 mm |

It will be understood that the characteristics and distances given in Tables I-IV are given by way of example. Those having ordinary skill in the art will be able to formulate other characteristics for the components, and distances between the components, without undue experimentation. Typically the formulation may be achieved using an optical simulation package such as ZEMAX software produced by ZEMAX Development Corporation, Bellevue, Wash.

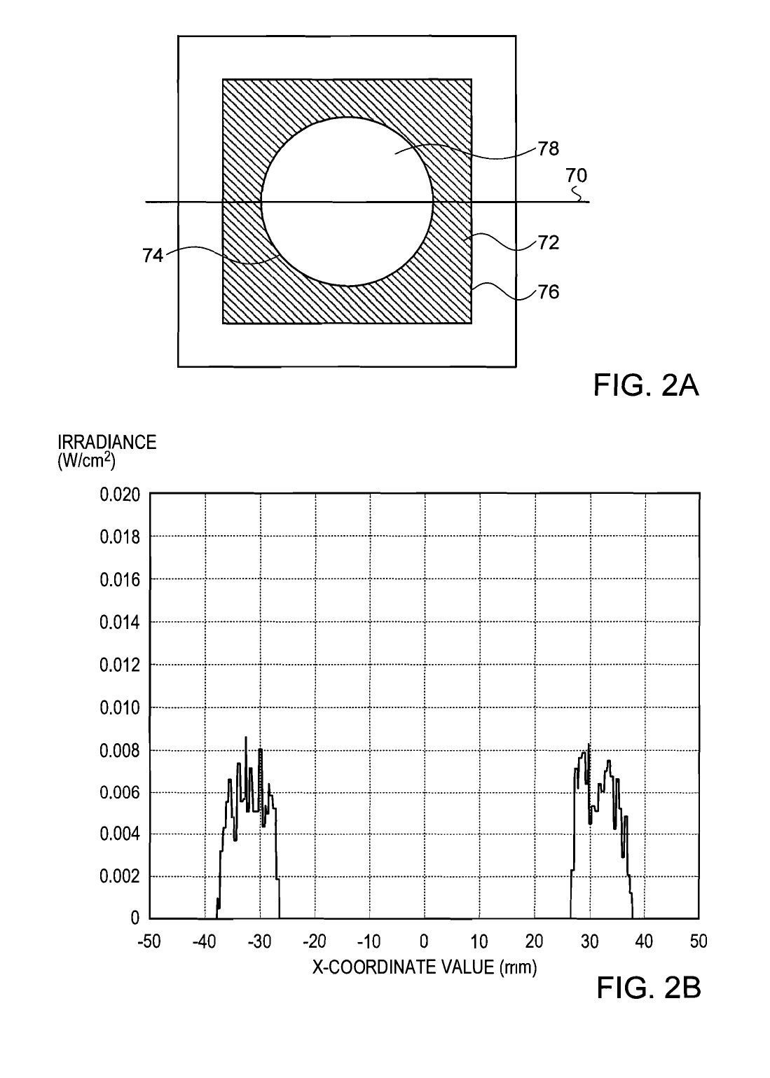

FIG. 2A is a schematic diagram showing irradiance at the position of secondary reflector 38 of system 24, due to reflection from the primary reflector, and FIG. 2B is a graph of the irradiance vs. distance, according to embodiments of the present invention. The diagram and graph are for the first exemplary embodiment of system 24 given above. The irradiance for FIG. 2A is plotted over a square region corresponding to the dimensions of the secondary reflector, i.e., 92 mm×92 mm. The graph of FIG. 2B plots the irradiance vs. distance along a symmetry line 70 of FIG. 2A.

All the reflected radiation from the primary reflector is incident on the secondary reflector. Shaded region 72 illustrates the region of the secondary reflector that receives the primary's reflected radiation. As shown by FIG. 2A, all the reflected radiation is contained within region 72 that is bounded by an inner circle 74 and an outer square 76 having an edge of approximately 80 mm. There is no reflected radiation from the primary reflector within a central region 78 having an external bound corresponding to inner circle 74.

Embodiments of the present invention take advantage of the absence of any reflected radiation in central region 78 by providing opening 44 in the secondary reflector, since such an opening causes no reduction in radiation at the primary reflector. Not only does opening 44 cause no reduction in radiation at the primary reflector, but it allows all central group 27 of incoming rays 28 to be converged through the opening onto the cell.

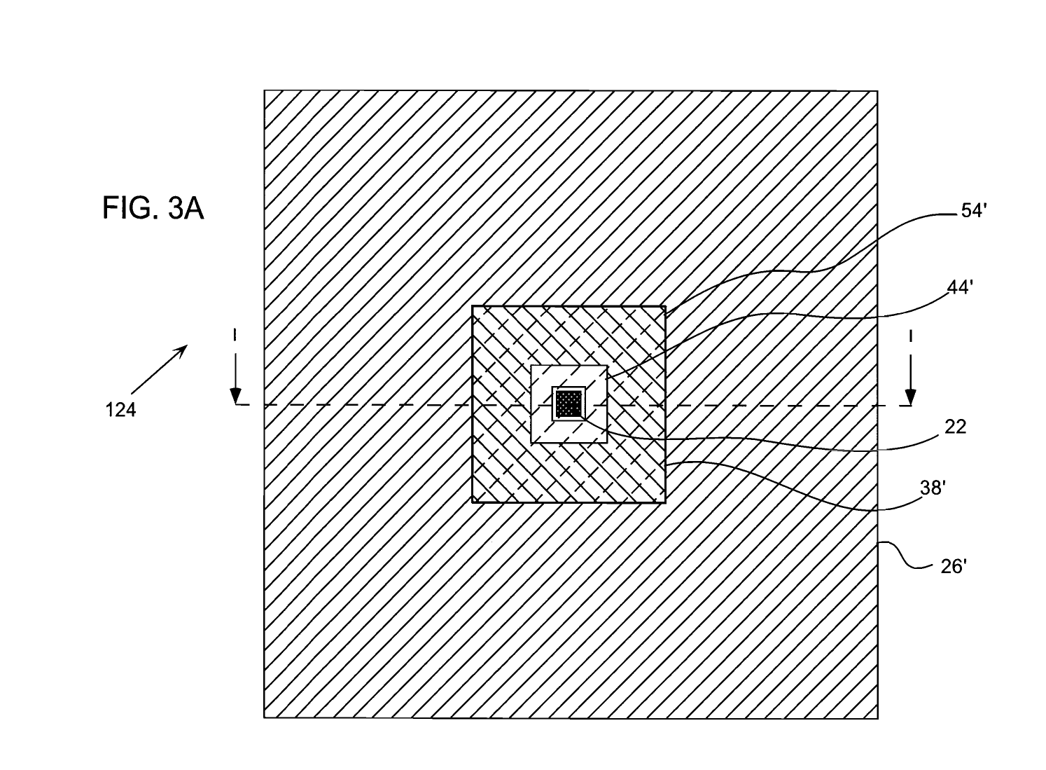

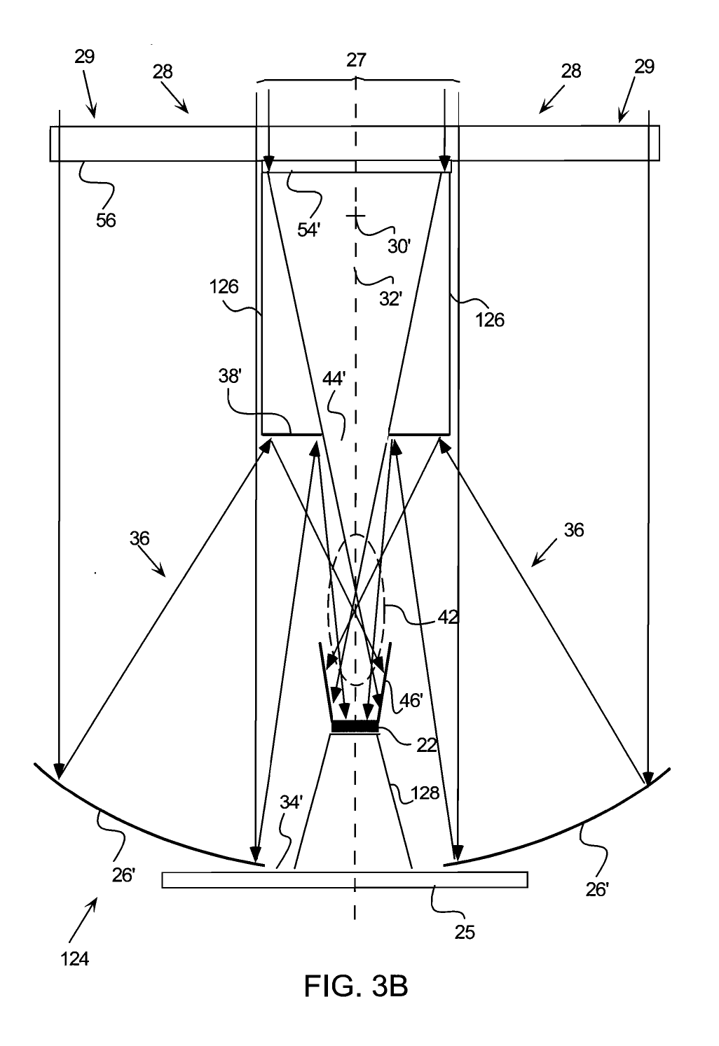

FIGS. 3A and 3B illustrate components of an alternative CPV system 124, according to an embodiment of the present invention. FIG. 3A is a top view of system 124 and FIG. 3B is a sectional side view. Apart from the differences described below, the operation of CPV system 124 is generally similar to that of CPV system 24 (FIGS. 1A, 1B, and 1C) and elements indicated by the same reference numerals in both systems 24 and 124 are generally similar in operation. Elements in system 124 having an apostrophe ' appended to the reference numeral may differ in dimensions from elements (of the exemplary embodiments of system 24 described above) having the same numeral.

In system 124, a concentrator 54′ and an aperture 34′ have substantially the same dimensions as a secondary reflector 38′. In addition, in system 124 a thin tube 126 fixedly connects the back of the secondary reflector to window 56. The tube acts as a support for the secondary reflector and has a minimal foot print to minimize shading losses.

In system 124 secondary reflector 38′ is flat, rather than being curved as in system 24.

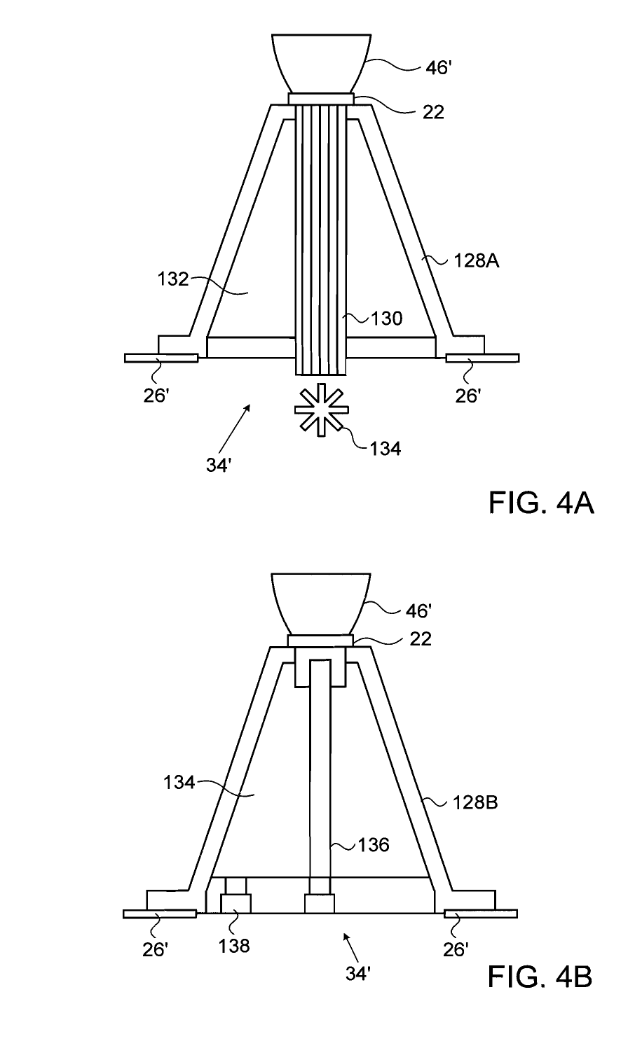

Also in contrast to system 24, in system 124 cell 22 and a homogenizer 46′ are positioned above the interior surface of primary reflector 26 by the cell and homogenizer being fixedly mounted on a cell mount 128. Mount 128 is configured to be sufficiently narrow so as to be completely in the shadow of secondary reflector 38′, so that none of peripheral group 29 of the incoming solar rays are prevented from reaching a primary reflector 26′. FIGS. 4A and 4B, referred to below, illustrate alternative designs for mount 128 and elements contained by the mount (not shown in FIG. 3B).

Repositioning cell 22 and homogenizer 46′ (from the locations of the cell and homogenizer of system 24 to those of system 124) requires repositioning of focal region 42. Region 42 may be repositioned by changing parameters, for example the focal lengths, of secondary reflector 38′ and concentrator 54′. Evaluation of such changes will be apparent to those having ordinary skill in the optical arts.

As for system 24, peripheral group 29 of rays pass directly to the primary reflector, and central group 27 of rays are converged by the concentrator to pass through an opening 44′ in the secondary reflector. Thus all incoming rays 28 are focused on cell 22.

Table V below gives characteristics of components of an exemplary embodiment of system 124. To differentiate the exemplary embodiments of the two systems (system 24 and system 124), the exemplary embodiment of system 124 is referred to as the third exemplary embodiment.

TABLE III

| Component | Characteristics |
|---|---|
| Concentrator 54′ | Square Fresnel lens or refractor, 95 mm × 95 mm, |
| | focal length 134 mm |
| Secondary reflector 38′ | Plane square mirror, 95 mm × 95 mm, i.e., |
| | congruent with the dimensions of concentrator |
| | 54′. The mirror has a central square opening |
| | (16 mm × 16 mm) to correspond with and be |
| | geometrically similar to the shape of concentrator |
| | 54′. |
| Primary reflector 26′ | Paraboloidal, square 250 mm × 250 mm, focal |
| | length 127 mm. Central aperture 34′ is a square |
| | 95 mm × 95 mm (corresponding with the |
| | dimensions and shape of concentrator 54′ and |
| | reflector 38′). |
| Solar cell 22 | Square, 10 mm × 10 mm |
| Homogenizer 46′ | Square truncated pyramid of BK7 optical glass. |
| | Length 47 mm, upper dimensions 14.1 mm × 14.1 |
| | mm, lower dimensions 9.8 mm × 9.8 mm |
| | (corresponding to, but slightly smaller than, the |
| | solar cell dimensions). |

Table IV below gives typical approximate distances between components of the third exemplary embodiment.

TABLE IV

| Components | Distance between Components |
|---|---|
| Concentrator 54′-secondary | 101.7 mm |
| reflector 38′ | |
| Secondary reflector 38′-top of | 24 mm |
| homogenizer 46′ | |
| Solar cell 22-aperture 34′ | 17.7 mm |

FIG. 4A illustrates a design for cell mount 128, and FIG. 4B illustrates an alternative design for the cell mount, according to embodiments of the present invention. For clarity, cell mount 128 illustrated in FIG. 4A is referred to as cell mount 128A, and cell mount 128 illustrated in FIG. 4B is referred to as cell mount 128B. As illustrated in FIGS. 4A and 4B, both cell mounts are assumed to be mounted over aperture 34′ of system 124.

Cell mount 128A (FIG. 4A) is an open structure, typically comprising two or more branches from cell 22 to the upper surface of the primary reflector. The open structure allows passage of air through the structure. A passive heat sink 130 is located in a space 132 of the mount, by being fixedly attached to the rear surface of cell 22. Heat sink 130 is typically a finned structure having a cross-section 134, and is formed from a good heat conductor such as copper or aluminum.

Cell mount 128B (FIG. 4B) is a closed structure, typically in the form of a closed hollow conical shape forming an enclosed space 134 in the mount. A cooling fluid, typically a gas such as air or a liquid such as water, is directed via a tube 136 to the rear surface of cell 22, exiting into space 132 after contacting the cell's rear surface. The cooling fluid exits from space 134 via an exit port 138.

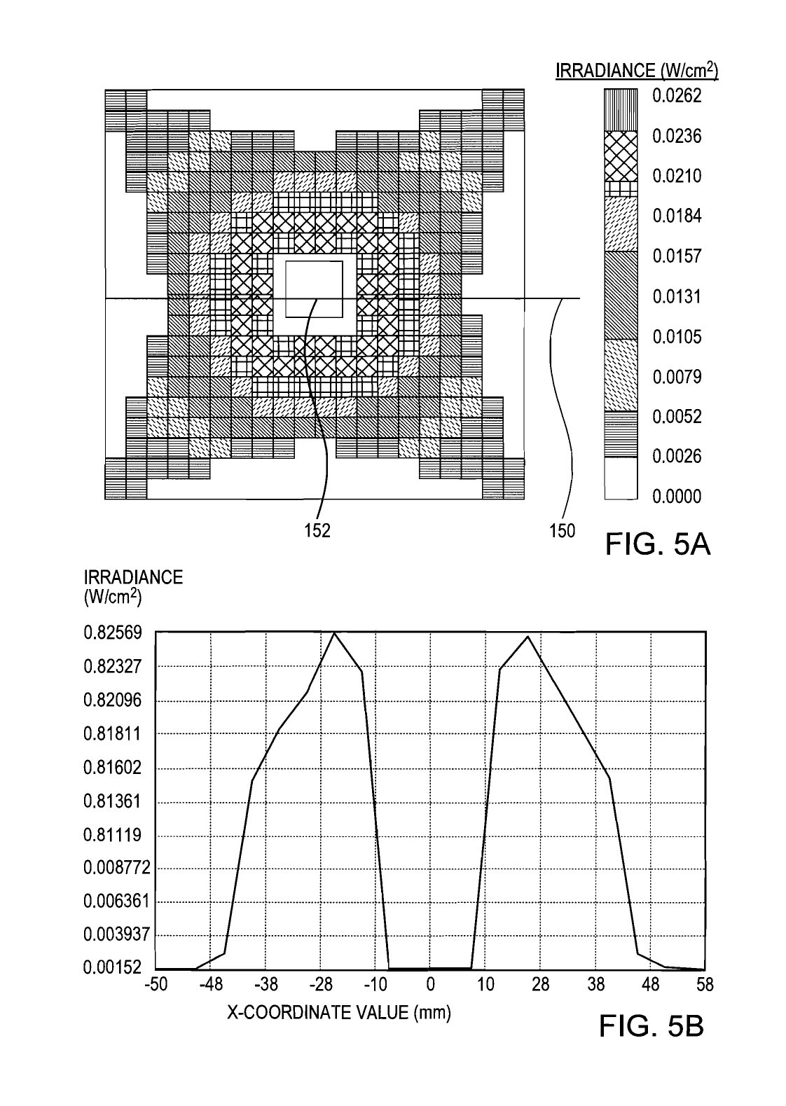

FIG. 5A is a schematic diagram showing irradiance at the position of secondary reflector 38′ of alternative CPV system 124, due to reflection from the primary reflector, and FIG. 5B is a graph of the irradiance vs. distance, according to embodiments of the present invention. The graph plots the irradiance vs. distance along a symmetry line 150 of FIG. 5A. As is apparent from comparison of the diagram and graph of FIGS. 5A and 5B with the diagram and graph of FIGS. 2A and 2B, irradiance features described above for the secondary reflector of system 24 are present in the secondary reflector of system 124. Thus in system 124, as for system 24, there is no reflected radiation from the primary reflector within a central region of the secondary reflector, illustrated in FIG. 5A as a region 152. Thus, in both system 24 and system 124 substantially all the reflected radiation from the primary reflector is incident on the secondary reflector of the system, and none is incident on a respective central region of the secondary reflector.

FIG. 6 is a schematic sectional side view of a matrix 200 of CPV systems 124, according to an embodiment of the present invention. For clarity and simplicity, individual elements of systems 124 are not labeled in FIG. 6. By way of example, matrix 200 is assumed to comprise six systems 124, arranged in a 2×3 rectangular array, so that the matrix is approximately 500 mm×750 mm. Alternatively, matrix 200 may comprise other numbers of systems 124, such as 24 systems arranged in a 4×6 array covering approximately 1 m×1.5 m.

Typically, the elements of the systems comprised in matrix 200 are mounted on a common base system mounting panel 202 by vertical supports 204 for the windows of the systems, and by structures 206 for the primary reflector. Each structure 206 is typically similar to skeleton-like section 62 of mount 60 (FIG. 1C). Panel 202 is in turn connected to a tracking device similar to that described above for system 24. In some embodiments, rather than having separate windows for each of CPV systems 124, one window 208, together with respective transmissive concentrators, covers all systems 124 in the matrix.

An electric junction box 210 may be attached to panel 202. Box 210 is typically configured to allow the electric power output from systems 124 to be connected in series, in parallel, or in a combination of series and parallel, according to requirements of a user of the matrix. (Typically, a side cover protects the panel from dust and moisture.)

It will be understood that a number of systems 24 may be arranged in matrices as described for systems 124. Furthermore, a mix of systems 24 and 124, and other CPV systems using the principles of CPV systems described herein, may be combined to form a matrix of CPV systems similar to matrix 200. One of these matrices may be used to replace a non-concentrating photovoltaic system of similar dimensions. For example, some non-concentrating photovoltaic systems have dimensions of approximately 1 m×1.5 m.

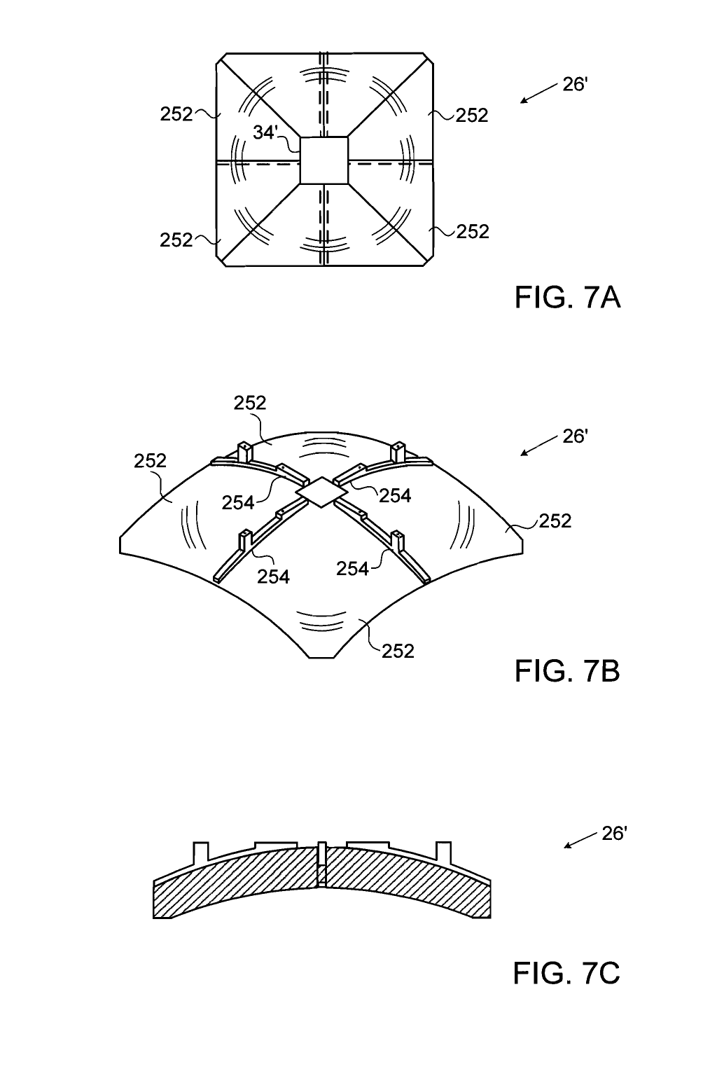

FIGS. 7A, 7B, and 7C are schematic front, back and side views respectively of primary reflector 26′ of system 124, according to an embodiment of the present invention. Primary reflector 26′ is made as a multi-segment reflector, which is formed by splitting the reflector into smaller curved segments for easy manufacturing and for better optical properties. The smaller segments are subsequently assembled to produce larger reflector 26′, with aperture 34′, as shown in these figures. By way of example, reflector 26′ is assumed to be made from four substantially identical segments 252.

The small curved segments may be made from flat metal sheet, such as aluminum, by stamping, which is generally a fast, low-cost operation. The stamp itself typically has a smaller radius of curvature than the desired segment shape, to account for spring-back of the metal after stamping. The exact shape of the stamp depends on the specific sheet metal that is used, and can be optimized by simple trial and error.

Before stamping, the sheet metal may be pre-coated with a reflective layer, or a flat pre-coated film may be applied to the metal sheet. Suitable materials for this purpose include Alanod 4270GP, produced by ALANOD Aluminium-Veredlung GmbH & Co, Ennepetal, Germany and ReflecTech Mirror Film, produced by ReflecTech Inc., Arvada, Colo. Data sheets for these materials may be found at www.alanod.de/opencms/export/alanod/Technik_gallery/datasheets/4270GP_E.pdf and www.reflectechsolar.com/pdfs/ReflecTechBrochuretoEmail22Aug08.pdf, and are incorporated herein by reference. Both materials are commercially available as reels of silver-coated film.

After stamping, the reflector segments are joined together to form a complete reflector assembly, as shown in the figures. For example, the segments can be glued on their back sides to a substrate, typically made of a low-cost material, which acts as a joint to hold the segments together. In the embodiment shown in FIGS. 7B and 7C, an aluminum profile is extruded with the exact parabolic shape of reflector 26′, and is then sliced into small ribs 254 that can be glued to the back of the assembled reflector to hold and join the segments together and to form a mounting base. Other suitable methods of assembling the segments will be apparent to those having ordinary skill in the art, such as by including clips in ribs 254, and attaching the segments to the ribs with the clips. All such methods are included in the scope of the present invention.

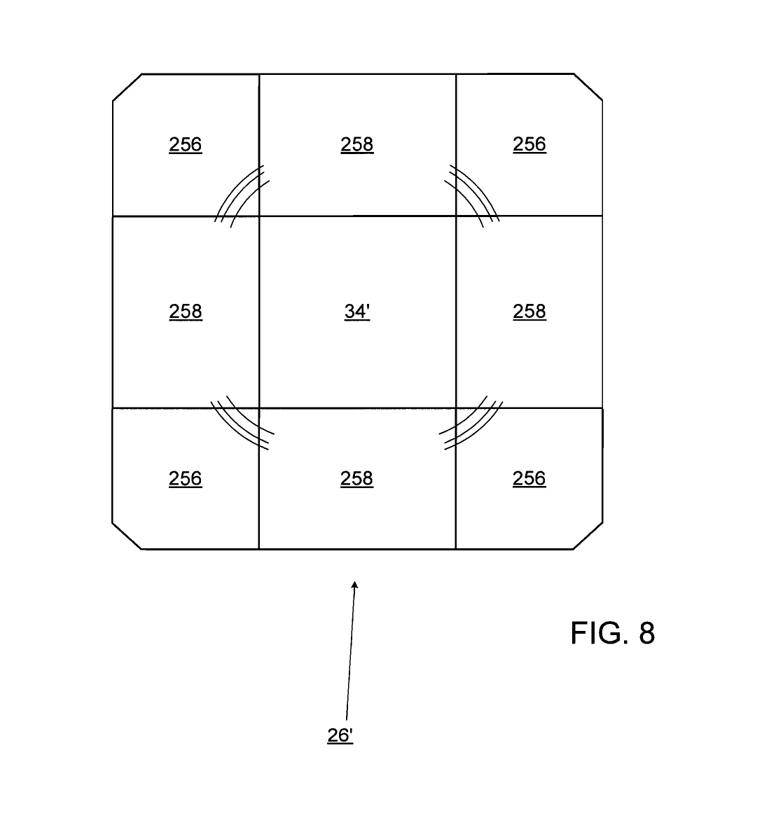

FIG. 8 is a schematic front view of primary reflector 26′, according to an alternative embodiment of the present invention. In the alternative embodiment, primary reflector 26′ is made as a multi-segment reflector by being formed from eight segments: four substantially similar square segments 256, and four substantially similar rectangular segments 258. It will be understood that the sizes of the square and rectangular segments are adjusted according to the dimensions of reflector 26′ and aperture 34′.

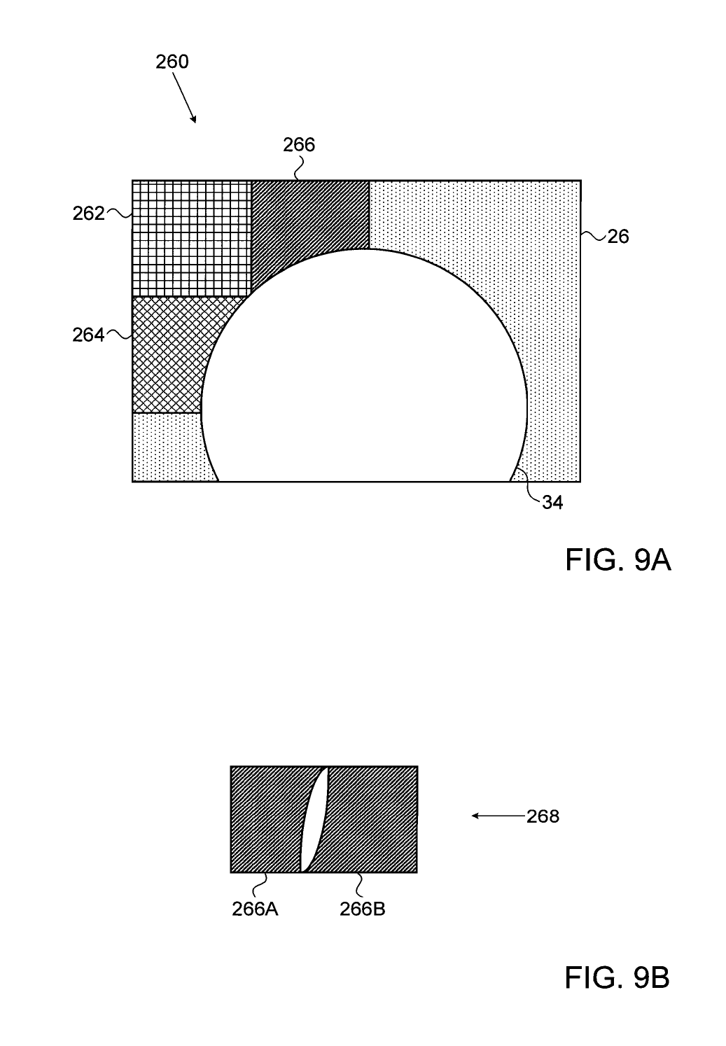

FIG. 9A is a schematic front view of segments of primary reflector 26 of system 24, and FIG. 9B is a schematic plan view of a plane sheet for producing some of the segments, according to an embodiment of the present invention. Reflector 26 is made as a multi-segment reflector comprised of 12 segments which are assembled to form the complete reflector, (substantially as described above with respect to the segments of reflector 26′ illustrated in FIGS. 7A, 7B, and 7C). For simplicity, in FIG. 9A only three segments of reflector 26 are shown, in a left quadrant 260 of the reflector, since the other nine segments (in the other three reflector quadrants) are typically reproductions of the three segments shown. For completeness, aperture 34 is shown in FIG. 9A.

Quadrant 260 is divided into a square segment 262 and two segments 264, 266 which are mirror images of each other. Typically, to produce segments 262 from a rectangular sheet, the sheet may initially be cut with substantially no wastage of material. In order to efficiently produce segments 264 and/or 266 from a rectangular sheet, the segments may initially be cut as is illustrated in diagram 268 (FIG. 9B) for two segments 266, labeled 266A and 266B in the diagram.

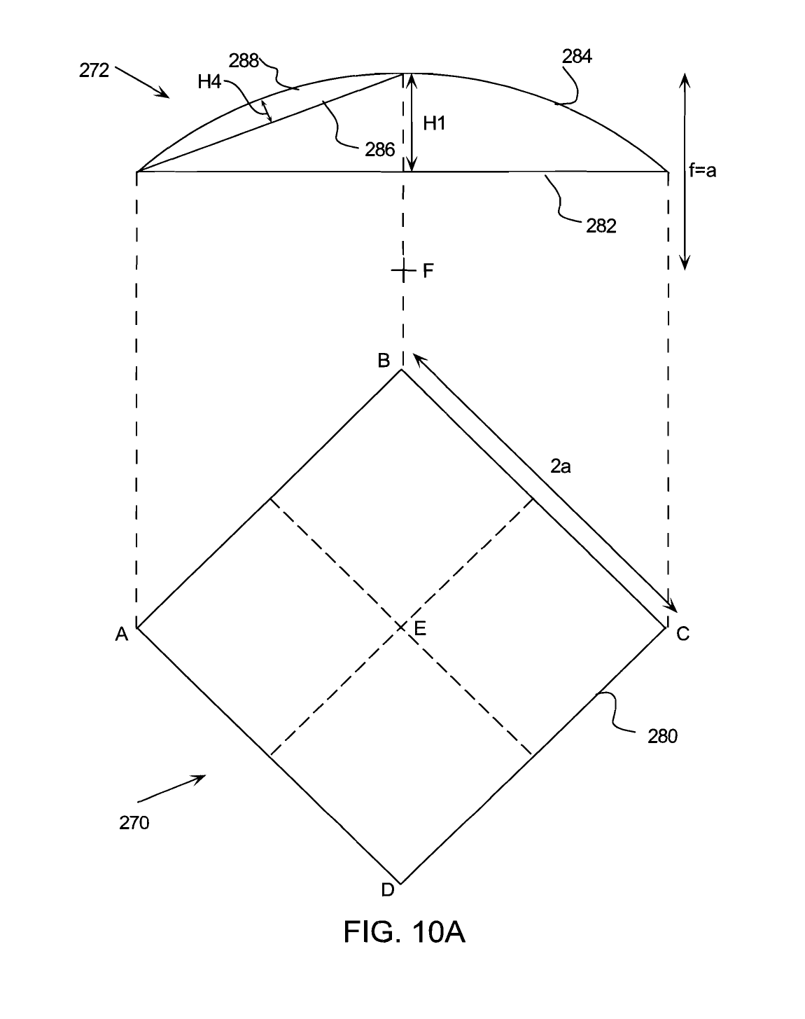

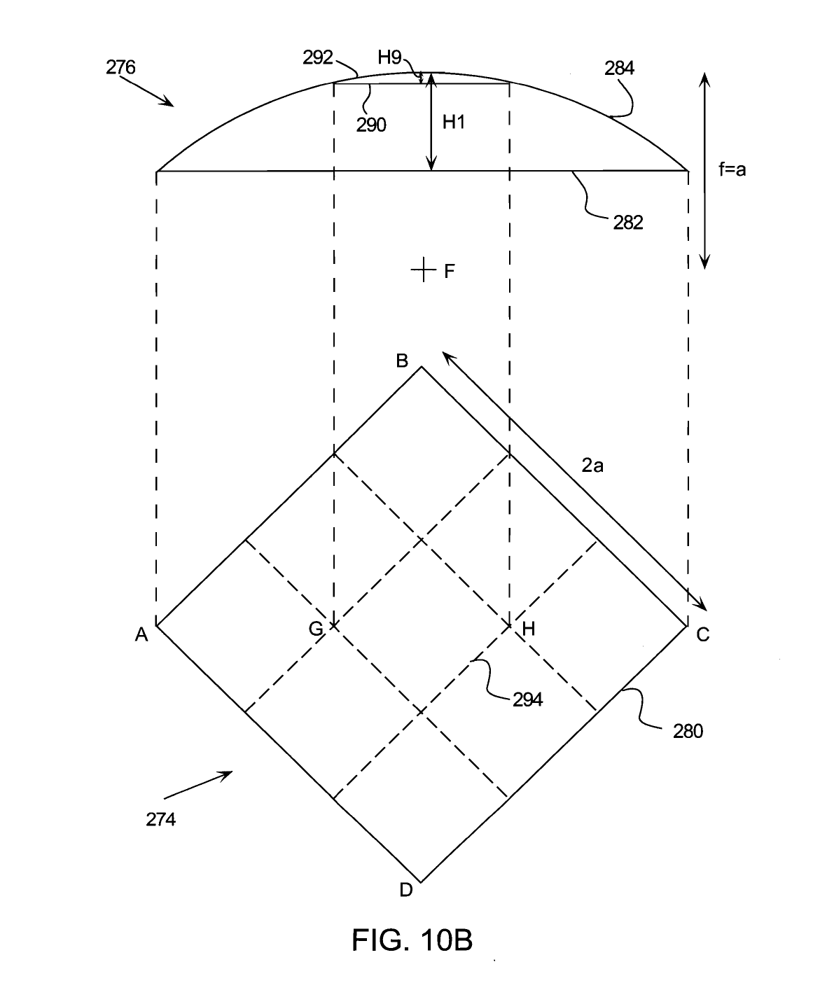

The descriptions above for FIGS. 7A, 7B, 7C, 8, 9A, and 9B assume that a 3-dimensional reflector, reflector 26 or reflector 26′, is created from segments smaller than the overall size of the reflector. Creating a 3-dimensional reflector by stamping a flat metal sheet introduces deformation, which can create voids within the reflective layer as well as between the reflective coating and the underlying metal, and thus reduce reflectivity and service life of the reflector. However, as explained below with reference to FIGS. 10A and 10B, by splitting the reflector into smaller segments, the deformation of each of the reflector segments is reduced.

FIG. 10A and FIG. 10B illustrate the reduction in deformation achieved by constructing a paraboloidal reflector such as reflector 26 or reflector 26′, from smaller segments, according to embodiments of the present invention. For simplicity, apertures in the reflector are not shown in the figures.

FIG. 10A illustrates constructing the reflector from four segments. In a diagram 270 solid lines illustrate a schematic top view of a single plane sheet 280, also herein termed sheet ABCD. Broken lines in the diagram show top views of edges of the segments producing the reflector. A diagram 272 shows schematic respective cross-sections 282, 284, of the single sheet before and after deformation into its paraboloidal shape. Cross-section 282 is taken along diagonal AC of sheet ABCD. Assuming the reflector is produced from four plane square sheets that are deformed into segments which are then joined together, diagram 272 shows schematic respective cross-sections 286, 288, of an exemplary one of the four sheets before deformation, and after deformation to its paraboloidal segment. Cross-section 286 is taken along the diagonal AE of the exemplary plane square sheet.

FIG. 10B illustrates splitting the reflector into nine segments, although typically only eight segments are used since a central aperture replaces the central segment. A diagram 274 is a schematic top view of single plane sheet 280. A diagram 276 shows cross-sections 282, 284, of the single sheet before and after deformation into its parabolic shape (as in FIG. 10A). Broken lines in the diagram show top views of edges of the segments producing the reflector. The reflector may be produced from eight or nine plane square sheets that are deformed into segments which are then joined together. Diagram 276 shows schematic respective cross-sections 290, 292, of a central segment 294 before and after deformation to its parabolic shape. Cross-section 290 is taken along the diagonal GH of the segment.

Details of the deformation calculations in the cases illustrated by FIGS. 10A and 10B are given in an Appendix of this disclosure. The calculations are for a square parabolic reflector having a focal length f equal to half the edge length 2a of a square. As is illustrated in the figures, for one plane sheet there is a depth change H1 of the sheet to produce the complete reflector. As is shown in the Appendix, H1=0.5a, and the change in area from the square plane to the square paraboloidal reflector, i.e., the deformation produced in the sheet, is an increase of almost 12%. Splitting the reflector into four segments gives a depth change for each segment of H4, where H4≈0.129a, and the deformation caused is an increase of only about 3% of the area of the plane segment.

Splitting the reflector into nine segments gives correspondingly smaller depth changes and deformations than the changes generated for four segments. Thus, central segment 294 has a depth change H9, where H9≈0.05a, and in this case the deformation is reduced to an increase of a little over 1%.

As stated above, suitable materials exist for pre-coating sheet metal with reflective material. Assuming this pre-coating, the production of parabolic reflectors from multiple segments reduces the deformation of the material to within the tolerance limits of the reflective material being used. It is therefore possible first to place the reflective coating on the sheet metal, using a reel of reflective material, and then to bend the metal. This process is substantially simpler and less costly than coating a curved shape. Furthermore, when the reflective sheeting is applied flat and then bent with the metal sheet as described above, the coated layer is more even and therefore has generally better performance than a coating applied to surfaces that are already curved.

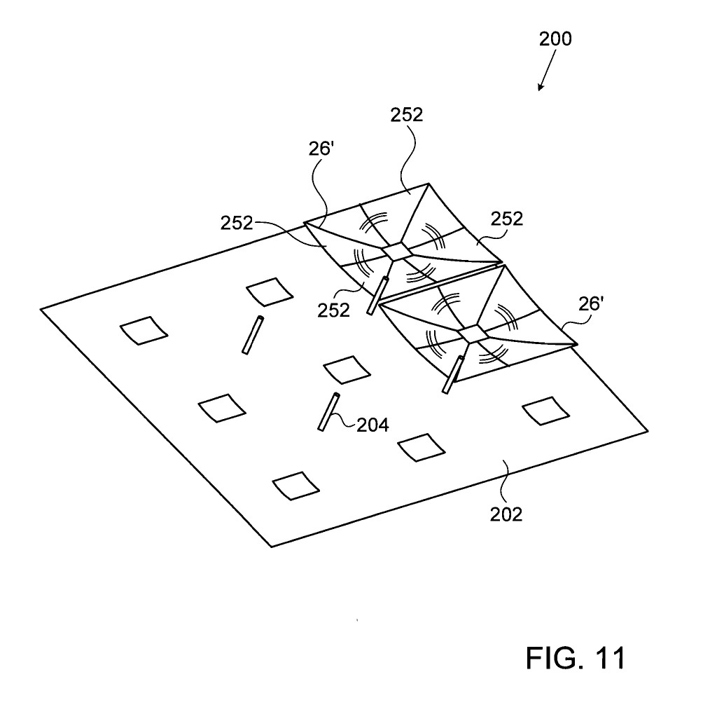

FIG. 11 is a schematic, pictorial illustration showing assembly of matrix 200 (FIG. 6) of CPV systems 124, according to an embodiment of the present invention. The diagram shows assembly of reflectors 26′ on panel 202. The component parabolic reflectors are made from four segments 252, which are then joined together on ribs 254, as shown in FIGS. 7A and 7B. The reflectors are mounted on base panel 202, along with vertical supports 204 for supporting the window and other components (not shown in FIG. 11). The CPV cells, homogenizers, windows and secondary reflectors of systems 124 are then assembled onto the base to complete the system, as shown in FIG. 6.

The description above refers generally to concentrators that concentrate incoming solar radiation onto a photovoltaic cell. However, it will be understood that solar concentrators such as are described herein may be used concentrate incoming solar radiation onto apparatus other then photovoltaic cells. For example, such an apparatus may comprise a thermocouple, or a plurality of thermocouples assembled as a thermopile, either of which systems may also be used to generate electricity. Furthermore, the apparatus receiving the concentrated solar radiation may be configured to convert the radiation to another energy form, such as chemical or thermal energy.

Although the description above includes forming a primary reflector from a number of smaller curved segments, it will be understood that substantially the same process may be applied to the formation of a secondary reflector.

It will thus be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

### APPENDIX

### Area Deformation Caused by Paraboloid Formation

The surface area Sₚ of a paraboloid (formed by the rotation of the parabola

$$y = \frac{{x}^{2}}{4 f} ,$$

f the focus of the paraboloid, about the y-axis) is given by:

$${S}_{p} = {\int }_{0}^{c} 2 π x \sqrt{( 1 + {( \frac{d y}{d x} )}^{2} )} d x \qquad ( 1 )$$

where c is the x-value of the edge of the paraboloid.

Assuming that the complete paraboloid is stamped from a square sheet having edge 2a, the largest x-value of the paraboloid is a\sqrt{2}. This is the value of c in equation (1).

From the equation for the parabola

$$( y = \frac{{x}^{2}}{4 f} )$$

$$\frac{d y}{d x} = \frac{x}{2 f} \qquad ( 2 )$$

Substituting the expressions for

$$\frac{d y}{d x}$$

and c into equation (1), and rearranging, gives:

$${S}_{p} = \frac{π}{f} {\int }_{x = 0}^{x = a \sqrt{2}} x \sqrt{( 4 {f}^{2} + {x}^{2} )} d x \qquad ( 3 )$$

Substituting u=4f²+x² (so that du=2×dx) into equation (3) gives:

$${S}_{p} = \frac{π}{2 f} {\int }_{u = 4 {f}^{2}}^{u = 4 {f}^{2} + 2 {a}^{2}} \sqrt{u} d u \qquad ( 4 )$$

Assuming that the plate is stamped so that f=a, equation (4) evaluates as:

$${S}_{p} = {\frac{π}{2 f} [ \frac{2}{3} {u}^{\frac{3}{2}} ]}_{4 {f}^{2}}^{6 {f}^{2}} = \frac{π {a}^{2}}{3} [ 6 \sqrt{6} - 8 ] \approx 7.013 {a}^{2} \qquad ( 5 )$$

A circular flat sheet of radius a\sqrt{2} has a surface area S_{f} given by:

S_{f}=2πa²≈6.28a² (6)

From equations (5) and (6) the percentage increase Δ₁ in surface area, when deforming the flat sheet to a paraboloid is given by:

$${Δ}_{1} = \frac{{S}_{p} - {S}_{f}}{{S}_{f}} = \frac{7.013 {a}^{2} - 6.28 {a}^{2}}{6.28 {a}^{2}} = 11.67 \% \qquad ( 7 )$$

### Approximation of Paraboloid by a Dome

From the equation

$$y = \frac{{x}^{2}}{4 f}$$

the paraboloid has a height h (from its vertex) given by:

$$h = \frac{{( a \sqrt{2} )}^{2}}{4 f} = \frac{a}{2} ( since a = f ) \qquad ( 8 )$$

At its edge, the paraboloid forms a circle of radius a\sqrt{2}.

In the following, we approximate the paraboloid to the curved surface of a dome (a section generated by a plane cutting a sphere). The dome has height h and radius r of the circle generated by the plane. In this case r=a\sqrt{2}.

By applying the Pythagoras theorem, the radius R_{c} of the sphere from which the dome is formed is given by:

$${R}_{c} = \frac{{h}^{2} + {r}^{2}}{2 h} = \frac{{h}^{2} + {( a \sqrt{2} )}^{2}}{2 h} = \frac{9 a}{4} \qquad ( 9 )$$

The area of the curved surface of a dome is given by:

A_{dome}=2πR_{c}h (10)

so that, substituting into equation (10) the values of R_{c} and h from equations (8) and (9),

$${A}_{dome} = \frac{9 π}{4} {a}^{2} \approx 7.068 {a}^{2} \qquad ( 11 )$$

The percentage error Δ₂ generated by using equation (10) instead of equation (3) is:

$${Δ}_{2} = \frac{7.068 - 7.013}{7.013} = 0.78 \% \qquad ( 12 )$$

Thus, the error between assuming that the area of the curved surface is spherical, compared to the paraboloidal shape of the surface, is less than 1%.

The error calculation is for r=a\sqrt{2}. For smaller values of r, the error is even less.

### Producing the Paraboloid in Four Segments

Considering FIG. 10A, for the parabola

$$y = \frac{{x}^{2}}{4 f}$$

(and assuming appropriate axes) section 286 has vertices (0,0) and

$$( a \sqrt{2} , \frac{{a}^{2}}{2 f} ) .$$

Since a=f, the length of the section is

$$\frac{3 a}{2} .$$

This is the diameter of the dome plane circle, so that the radius is

$$\frac{3 a}{4}$$

Assuming

$${R}_{c} = \frac{9 a}{4} ,$$

and using equation (9) with

$$r = \frac{3 a}{4}$$

to solve for H4. the height of the dome, gives:

$$H 4 = \frac{2 {R}_{c} \pm \sqrt{{( 2 {R}_{c} )}^{2} - 4 {r}^{2}}}{2} = \frac{2 \frac{9 a}{4} \pm \sqrt{4 {( \frac{9 a}{4} )}^{2} - 4 {( \frac{3 a}{4} )}^{2}}}{2} \qquad ( 13 )$$

Equation (13) simplifies to:

$$H 4 = \frac{( 9 - 6 \sqrt{2} )}{4} a \approx 0.129 a \qquad ( 14 )$$

From equation (10) the area of the curved surface of the dome is:

$${A}_{dome} = 2 π {R}_{c} H 4 = 2 π \frac{9 a}{4} 0.129 \approx 1.824 {a}^{2} \qquad ( 15 )$$

The area of a flat sheet with radius

$$\frac{3 a}{4}$$

is:

$${A}_{flat} = {π ( \frac{3 a}{4} )}^{2} \approx 1.767 {a}^{2} \qquad ( 16 )$$

From equations (15) and (16) the percentage increase Δ₄ in surface area, when deforming the flat sheet to a paraboloidal segment is given by:

$${Δ}_{4} = \frac{{A}_{dome} - {A}_{flat}}{{A}_{flat}} = \frac{1.824 {a}^{2} - 1.767 {a}^{2}}{1.767 {a}^{2}} = 3.23 \% \qquad ( 17 )$$

Comparing equations (7) and (17), it is apparent that the deformation caused by the smaller paraboloidal segment decreases significantly.

### Producing the Paraboloid in Nine Segments

Considering FIG. 10B, section 290 has a length GH, which is equal to

$$\frac{a \sqrt{8}}{3}$$

This is the diameter of the dome plane circle, so that the radius is

$$\frac{a \sqrt{8}}{6} .$$

Using this value of radius, and applying the same operations as equations (13) and (14) gives a value for H9:

H9≈0.05a (18)

Applying the same operations as equations (15) and (16) gives:

$$\begin{matrix}{A}_{dome} = 2 π {R}_{c} H 9 = 2 π \frac{9 a}{4} 0.05 a \approx 0.706 {a}^{2} \\ {A}_{flat} = {π ( \frac{a \sqrt{8}}{6} )}^{2} \approx 0.698 {a}^{2}\end{matrix} \} \qquad ( 19 )$$

From equations (19) the percentage increase Δ₉ in surface area, when deforming the central flat sheet to the central paraboloidal segment is given by:

$${Δ}_{9} = \frac{{A}_{dome} - {A}_{flat}}{{A}_{flat}} = \frac{0.706 {a}^{2} - 0.698 {a}^{2}}{0.698 {a}^{2}} = 1.146 \% \qquad ( 20 )$$

A generally similar percentage increase in surface area occurs for the other eight paraboloidal segments, all increases being smaller than the value of 3.23% given by equation (17).

1. Apparatus, comprising:
a photovoltaic cell;
a concave primary reflector configured to focus a first portion of incoming radiation toward a focal point;
a secondary reflector, which is positioned between the concave primary reflector and the focal point so as to direct the focused radiation toward the photovoltaic cell, and which has a central opening aligned with the photovoltaic cell; and
a transmissive concentrator, positioned so as to focus a second portion of the incoming radiation through the central opening onto the photovoltaic cell.

2. The apparatus according to claim 1, wherein at least one of the primary reflector and the secondary reflector comprise a plurality of curved segments.

3. The apparatus according to claim 1 further comprising a tracking device connected to the photovoltaic cell, the primary reflector, the secondary reflector, and the transmissive concentrator, wherein the primary reflector has an aperture, and wherein dimensions of the transmissive concentrator and the aperture differ by no more than a value determined in response to a tracking error of the tracking device.

4. The apparatus according to claim 1, wherein the transmissive concentrator has a concentrator-dimension larger than a largest dimension of the secondary reflector.

5. The apparatus according to claim 1, wherein the transmissive concentrator and the secondary reflector have congruent external dimensions.

6. The apparatus according to claim 1, wherein a shape of the transmissive concentrator is geometrically similar to the central opening.

7. The apparatus according to claim 1, and comprising a homogenizer, positioned between the secondary reflector and the photovoltaic cell, which redirects at least some of the focused radiation onto the photovoltaic cell.

8. The apparatus according to claim 1, and comprising a homogenizer, positioned between the secondary reflector and the photovoltaic cell, which redirects at least some of the second portion of the radiation onto the photovoltaic cell.

9. The apparatus according to claim 1, wherein the central opening is aligned and dimensioned within the secondary reflector so as to receive none of the focused radiation.

10. The apparatus according to claim 1, wherein the transmissive concentrator has a concentrator-dimension larger than a largest dimension of the central opening.

11. The apparatus according to claim 1, wherein the concave primary reflector comprises a paraboloidal reflector.

12. A method, comprising:
stamping flat metal plates so as to create a plurality of segments having a predetermined curved shape; and
joining the curved segments together in order to create a curved reflector.

13. The method according to claim 12, and comprising applying a reflective coating to the metal plates prior to stamping the plates.

14. The method according to claim 13, wherein a deformation caused by stamping the flat metal plates is within a tolerance limit of the reflective coating.

15. The method according to claim 12, wherein the predetermined curved shape and the curved reflector are sections of a common paraboloid.

16. A method, comprising:
configuring a concave primary reflector to focus a first portion of incoming radiation toward a focal point;
positioning a secondary reflector between the concave primary reflector and the focal point so as to direct the focused radiation toward a photovoltaic cell;
aligning a central opening in the secondary reflector with the photovoltaic cell; and
positioning a transmissive concentrator to focus a second portion of the incoming radiation through the central opening onto the photovoltaic cell.

17. The method according to claim 16, wherein at least one of the primary reflector and the secondary reflector comprise a plurality of curved segments.

18. The method according to claim 16, further comprising connecting a tracking device to the photovoltaic cell, the primary reflector, the secondary reflector, and the transmissive concentrator, and comprising forming an aperture in the primary reflector, wherein dimensions of the transmissive concentrator and the aperture differ by no more than a value determined in response to a tracking error of the tracking device.

19. The method according to claim 16, wherein the transmissive concentrator has a concentrator-dimension larger than a largest dimension of the secondary reflector.

20. The method according to claim 16, wherein the transmissive concentrator and the secondary reflector have congruent external dimensions.

21. The method according to claim 16, and comprising shaping the transmissive concentrator to be geometrically similar to the central opening.

22. The method according to claim 16, and comprising positioning a homogenizer between the secondary reflector and the photovoltaic cell, and configuring the homogenizer to redirect at least some of the focused radiation onto the photovoltaic cell.

23. The method according to claim 16, and comprising positioning a homogenizer between the secondary reflector and the photovoltaic cell, and configuring the homogenizer to redirect at least some of the second portion of the radiation onto the photovoltaic cell.

24. The method according to claim 16, and comprising aligning and dimensioning the central opening within the secondary reflector so as to receive none of the focused radiation.

25. The method according to claim 16, wherein the transmissive concentrator has a concentrator-dimension larger than a largest dimension of the central opening.

26. The method according to claim 16, wherein the concave primary reflector comprises a paraboloidal reflector.

27. The method according to claim 16, wherein configuring the concave primary reflector and positioning the secondary reflector comprise assembling and aligning the primary and secondary reflector as a composite unit prior to mounting the composite unit on a system mounting panel.

28. Apparatus, comprising:
a plurality of flat metal plates which are configured to form respective curved segments having respective predetermined curved shapes; and
at least one joint which holds the curved segments together in order to create a curved reflector.

29. The apparatus according to claim 28, and comprising a reflective coating which is applied to the metal plates prior to forming the respective curved segments.

30. The apparatus according to claim 29, wherein a deformation caused by forming the respective curved segments is within a tolerance limit of the reflective coating.

31. The apparatus according to claim 28, wherein the predetermined curved shapes and the curved reflector are sections of a paraboloid.

32. The apparatus according to claim 28, wherein the at least one joint comprises ribs having rib-cross-sections corresponding with a cross-section of the curved reflector.
